(19) United States
(12) Patent Application Publication
(10) Pub. No.: US 2013/0203248 A1
(43) Pub. Date: Aug. 8, 2013

(54) INTEGRATED CIRCUIT HAVING A JUNCTIONLESS DEPLETION-MODE FET DEVICE

(71) Applicants: Thomas Ernst, Morette (FR); Marie-Anne Jaud, Claix (FR); Perrine Batude, Grenoble (FR)

(72) Inventors: Thomas Ernst, Morette (FR); Marie-Anne Jaud, Claix (FR); Perrine Batude, Grenoble (FR)

(73) Assignee: Commissariat a l'energie atomique et aux energies alternatives, Paris (FR)

(21) Appl. No.: 13/702,226

(22) PCT Filed: Jun. 6, 2011
(86) PCT No.: PCT/EP11/59301

§ 371 Date: Apr. 17, 2013

(30) Foreign Application Priority Data
Jun. 7, 2010 (FR) 1054455

(51) Int. Cl. H01L 21/74

(52) U.S. Cl. CPC H01L 21/743
USPC 438/530

(57) ABSTRACT

A method for producing an integrated circuit, including, in this order: a) producing at least one MOS electronic circuit and/or at least one level of electrical interconnections on a substrate; b) uniformly implantating dopants in at least a portion of a layer of crystalline semiconductor; c) thermally activating the dopants implanted in the portion of the crystalline semiconductor layer; d) rigidly connecting the crystalline semiconductor layer to the substrate; and e) producing at least one junctionless depletion-mode FET device including a part of the portion of the crystalline semiconductor layer.

### TECHNICAL FIELD

The invention relates to the field of integrated circuits, and more specifically that of three-dimensional integrated circuits, including several electronic levels superposed on one another, where each level includes one or more microelectronic devices such as field-effect transistors (FETs) and/or electrical interconnections. The invention also relates to a method of producing integrated circuit.

The invention relates in particular to the production of very dense three-dimensional integrated circuits comprising several electronic levels, including microelectronic devices which are interconnected by levels of electrical interconnections.

The invention has many applications in the fields of electronic using structures of the FET type, such as that of reconfigurable logics, three-dimensional static memories (SRAM), three-dimensional flash memories, addressing of memories, NEMS (electromechanical nanosystems) sensors, ChemFET chemical sensors, etc.

### STATE OF THE PRIOR ART

To improve the compactness of integrated circuits, it is sought to increase the density of integration of the electronic components and of the electrical interconnections forming part of these integrated circuits.

One way to increase this integration density is to produce three-dimensional integrated circuits, i.e. circuits including several electronic levels superposed on one another, where each level includes one or more microelectronic devices, such as field-effect transistors (FETs), connected to levels of electrical interconnections.

Document “3-D Hyperintegration and Packaging Technologies for Micro-Nano Systems” by J. Q. LU, Proceedings of the IEEE, vol. 97, n° 1, January 2009, describes several types of three-dimensional integrated circuits. To produce such integrated circuits the different levels of the integrated circuit must firstly be produced independently of one another on different substrates. These levels are then secured to one another, and then interconnected by through-silicon vias, and electrical interconnections are made between the different levels to connect electrically the elements produced on these levels.

Such an integrated circuit production method does not however enable very high integration densities to be obtained bearing in mind the alignment tolerances between the electronic devices of the different levels, which must be taken into account when rigidly connecting the different levels.

One variant embodiment of such three-dimensional integrated circuits consists in firstly producing the electronic elements of a first level on a first substrate, and in then producing the electronic elements of a second level on a second substrate, having previously secured the second substrate to the first substrate.

This variant enables the alignment tolerances between the electronic devices of the different levels to be disregarded, since the devices of the second level are produced only after the second substrate has been secured to the first substrate. By this means, only the tolerance due to the inaccuracies of the lithographic steps implemented to produce the devices of the second level must be taken into account, which enables a greater integration density of the electronic components and of the electrical interconnections to be obtained in an integrated circuit produced in this manner.

Such a method of production of integrated circuits poses problems, however, when it is desired to produce devices requiring the implementation of steps involving substantial thermal budgets, such as for example MOSFET transistors, above levels including electrical interconnections and/or other MOSFET transistors. Indeed, when MOSFET transistors are produced a step of thermal activation of the dopants implanted in an active layer, in the transistors' source and drain areas, must be implemented. Such a thermal activation step must generally be implemented, in the case of silicon, at a temperature of above approximately 850° C. However, the presence of electrical interconnections under the active layer containing the dopants to be activated is incompatible with the implementation of such thermal activation, bearing in mind the excessively high temperatures which must be attained. This incompatibility is also found when the lower level includes MOSFET transistors which are then damaged if such a thermal activation is accomplished to activate the dopants of an active layer superposed on these transistors.

The document “System on Wafer: A New Silicon Concept in SiP” by G. Poupon et al., Proceedings of the IEEE, vol. 97, n° 1, January 2009, describes a three-dimensional integrated circuit in which a first level includes FET transistors of the nMOS type produced in an active silicon layer, and a second level, positioned above the first level, includes FET transistors of the pMOS type produced in an active germanium layer. Given that the transistors of the second level are of the pMOS type and are produced in an active germanium layer, the activation temperature of the dopants of these transistors is less than approximately 600° C., and does not therefore damage, or damages only slightly, the nMOS transistors produced in the lower active silicon layer. A three-dimensional integrated circuit with SoI (silicon on insulator)/GeOI (germanium on insulator) co-integration is therefore obtained.

Such an integrated circuit does however have the disadvantage that it is limited to superposing pMOS type transistors on nMOS transistors, and that the upper active layer must necessarily be made of germanium. In addition, the activation temperature is higher than the maximum temperature tolerated by copper-based interconnections which are used for advanced technological nodes, and which cannot withstand temperatures higher than approximately 450° C. Such a circuit does not therefore enable one or more levels of transistors to be produced above such interconnections. Other materials which are less sensitive to the thermal budgets, for example tungsten, can be envisaged to produce the interconnections, but the higher resistivity of these materials would then impair the dynamic performance of the circuit.

### DESCRIPTION OF THE INVENTION

One aim of the present invention is to propose a new type of integrated circuit with an FET device which does not have the disadvantages of the integrated circuits of the prior art, i.e. enabling it to be produced with very high integration density, without being restricted to a particular nature of the materials and/or of the dopants used in the integrated circuit, nor being restricted in terms of the number of superposed levels which the integrated circuit may include, nor in the use of particular interconnections which must withstand a high thermal budget.

To this end an integrated circuit is proposed which comprises at least:
one substrate on which at least one MOS electronic circuit and/or at least one level of electrical interconnections is produced,
a junctionless depletion-mode FET device including at least one uniformly doped crystalline semiconductor part secured to the substrate.

The invention relates to a method to produce such an integrated circuit. This integrated circuit makes use of a junctionless depletion-mode FET device. Compared to a conventional MOSFET device, a junctionless depletion-mode FET device does not have any junctions, for example of the p-n or n-n+ or p-p+ types, formed between the source and the channel, or between the drain and the channel. The source, the drain and the channel are formed in the uniformly doped semiconductor part. The fact that the semiconductor part is uniformly doped means that there is no variation of dopant concentration in the semiconductor part. Whether or not a current flows between the source and the drain is thus controlled only by whether or not a depletion area is created in the channel region.

By using a junctionless depletion-mode FET device the structure of the integrated circuit can therefore have one or more crystalline FET devices, for example transistors, produced above and/or between levels of electrical interconnections and/or other MOS electronic circuits.

The integrated circuit may also include at least one layer comprising a dielectric material covering the substrate and the MOS electronic circuit and/or the level of electrical interconnections, and positioned between the substrate and the junctionless depletion-mode FET device. The layer comprising the dielectric material may also be a stack of several layers made of one or more dielectric materials.

The integrated circuit may also include multiple levels of electrical interconnections positioned in the layer (or stack of layers) made of the dielectric material, where the MOS electronic circuit may include several MOS transistors connected electrically to the levels of electrical interconnections by vias formed in the layer comprising the dielectric material.

The integrated circuit may also include at least one second layer (or a second stack of layers) comprising a dielectric material covering at least the junctionless depletion-mode FET device, and at least one level of electrical interconnections positioned in the second layer comprising the dielectric material connected electrically to the junctionless depletion-mode FET device by vias formed in the second layer comprising dielectric material.

The uniformly doped crystalline semiconductor part may form one or more nanowires of uniformly doped crystalline semiconductor.

The junctionless depletion-mode FET device may be a transistor including a channel, a source and a drain formed by the uniformly doped crystalline semiconductor part.

The junctionless depletion-mode FET device may include at least one front gate and/or one back gate positioned opposite the channel of the junctionless depletion-mode FET device.

The junctionless depletion-mode FET device may include, between the front gate and the channel and/or between the back gate and the channel, at least one part of material able to store electrical charges and positioned between at least two parts of dielectric material. Such an FET device then forms a non-volatile memory device, where the “gate dielectric”, i.e. the structure between the channel and the gate, may then comprise a stack of the oxide/storage layer/oxide type, or any other type of stack enabling electrical charges to be stored (SiO₂/SiN/SiO₂, SiO₂/Si/SiO₂, etc.). In the case of an intermediate layer, or charge storage layer, comprising silicon or any other appropriate conductive layer, such a layer then forms a floating gate in which a signal can be stored.

The junctionless depletion-mode FET device may be a flash memory transistor.

The junctionless depletion-mode FET device may be a chemical sensor of the junctionless depletion-mode ChemFET type.

The integrated circuit may also include at least one bonding layer and/or one barrier layer and/or one stop layer positioned between the substrate and the junctionless depletion-mode FET device.

The invention relates in particular to a method for producing an integrated circuit, including at least, in this order, the following steps:
a) production of at least one MOS electronic circuit and/or at least one level of electrical interconnections on a substrate,
b) uniform implantation of dopants in at least a portion of a crystalline semiconductor layer,
c) thermal activation of the dopants implanted in the portion of the crystalline semiconductor layer,
d) rigid connection of the crystalline semiconductor layer to the substrate,
e) production of at least one junctionless depletion-mode FET device including a part of the portion of the crystalline semiconductor layer.

Given that thermal activation of the dopants implanted in the crystalline semiconductor layer is accomplished while the layer is not yet rigidly connected, or secured, to the substrate, this step of thermal activation does not damage the MOS electronic circuit and/or the level(s) of electrical interconnections on the substrate.

In addition, given that the junctionless depletion-mode FET device is produced after having rigidly connected the crystalline semiconductor layer, the alignment tolerances between the junctionless depletion-mode FET device and other elements of the integrated circuit can be disregarded. Only the tolerance due to the inaccuracies of the lithographic steps implemented to produce the junctionless depletion-mode FET device can be taken into account.

The method may also include, between steps a) and d), for example between steps a) and b), a step of production of at least one layer comprising, or made of, a dielectric material covering the substrate and the MOS electronic circuit and/or the level of electrical interconnections, where the crystalline semiconductor layer is secured to the substrate, in step d), with the layer comprising the dielectric material in between.

The method may also include, during production of the layer comprising the dielectric material, the production of multiple levels of electrical interconnections positioned in the layer comprising the dielectric material, where the MOS electronic circuit includes several MOS transistors electrically connected to the levels of electrical interconnections by vias formed in the layer comprising the dielectric material.

The crystalline semiconductor layer may be a surface layer of an SOI substrate, and the method may also include, between steps d) and e), a step of separation of the semiconductor layer and other elements of the SOI substrate.

Step e) of production of the junctionless depletion-mode FET device may be implemented at a temperature of less than approximately 450° C.

Step e) of production of the junctionless depletion-mode FET device may include the production of an area of electrical insulation in the crystalline semiconductor layer, around the part of the portion of the crystalline semiconductor layer.

Step e) of production of the junctionless depletion-mode FET device may include etching of the crystalline semiconductor layer around the part of the portion of the crystalline semiconductor layer, where said part forms one or more nanowires of uniformly doped crystalline semiconductor.

The method may also include, after step e) of production of the junctionless depletion-mode FET device, production of at least one second layer comprising, or made of, a dielectric material covering at least the junctionless depletion-mode FET device, and at least one level of electrical interconnections positioned in the second layer comprising the dielectric material electrically connected to the junctionless depletion-mode FET device by vias formed in the second layer comprising the dielectric material.

The method may also include, after step c), deposition of at least one gate dielectric or the production of a stack including at least one part of material able to store electrical charges positioned between at least two parts of dielectric material, on the crystalline semiconductor layer, and production of at least one front gate and/or one back gate opposite the channel of the junctionless depletion-mode FET device, where the gate dielectric or said stack may be positioned between the front gate and the channel and/or between the back gate and the channel. The gate dielectric may notably be made of SiO₂ and be produced, for example, at a temperature of over approximately 700° C. Such a gate dielectric may also be formed by a stack of several parts of dielectric materials, for example a stack of the ONO (oxide/nitride/oxide) type.

The method may also include, between steps b) and c) or between steps c) and d), deposition, on the crystalline semiconductor layer, of at least one bonding layer and/or one barrier layer and/or one stop layer. This or these intermediate layer(s), for example comprising dielectric materials, can, for example, enable out-diffusion of dopants during step c) to be prevented, and/or form an interface layer in step d) of rigid connection, which may be a molecular bonding, and/or form a stop layer for subsequent steps of cleaning or etching.

The method may also include, before implementation of step d), rigid connection of the crystalline semiconductor layer to a temporary handle, and also include, between steps d) and e), elimination of the temporary handle. It is thus possible to manipulate the crystalline semiconductor layer easily by means of the temporary handle.

### BRIEF DESCRIPTION OF THE ILLUSTRATIONS

The present invention will be better understood on reading the description of example embodiments given purely as an indication and in no way restrictively, making reference to the appended illustrations in which:

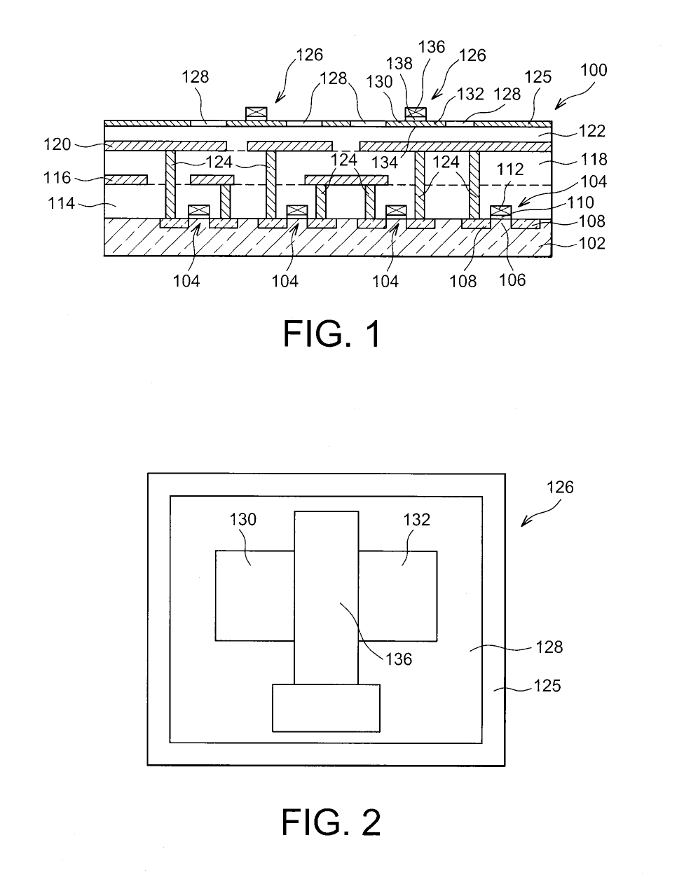

FIGS. 1, 3, and 5 to 7 represent integrated circuits with junctionless depletion-mode FET devices produced according to a method forming the object of the present invention, respectively according to several embodiments,

FIGS. 2, 4 and 8 represent examples of junctionless depletion-mode FET devices of integrated circuits produced according to a method forming the object of the present invention,

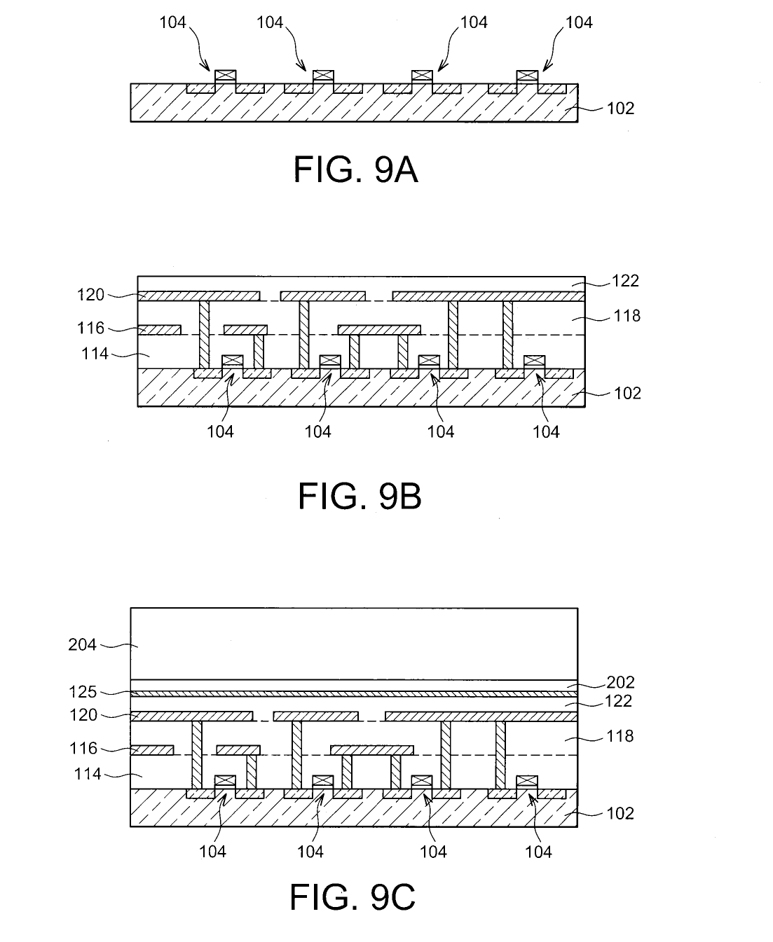

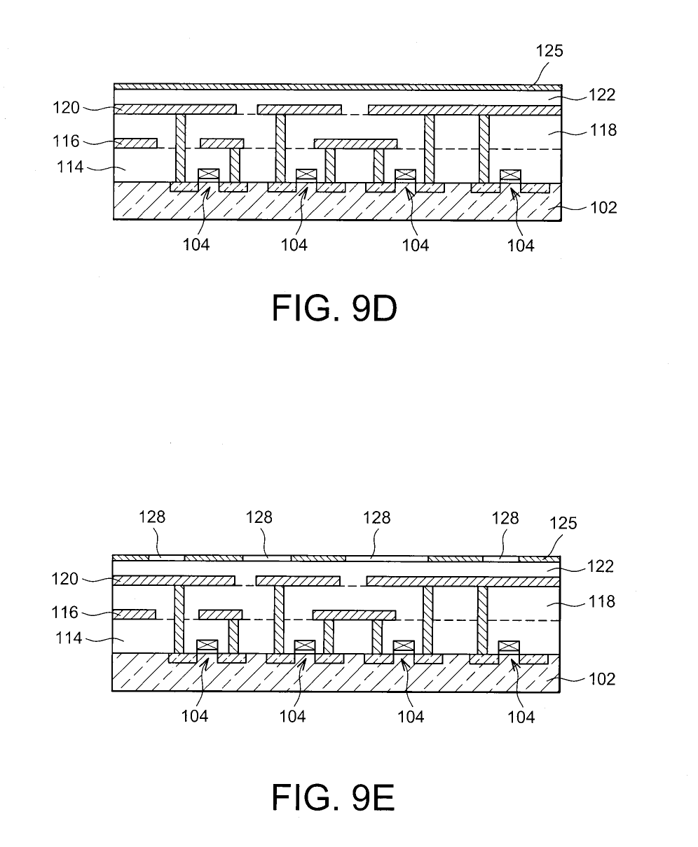

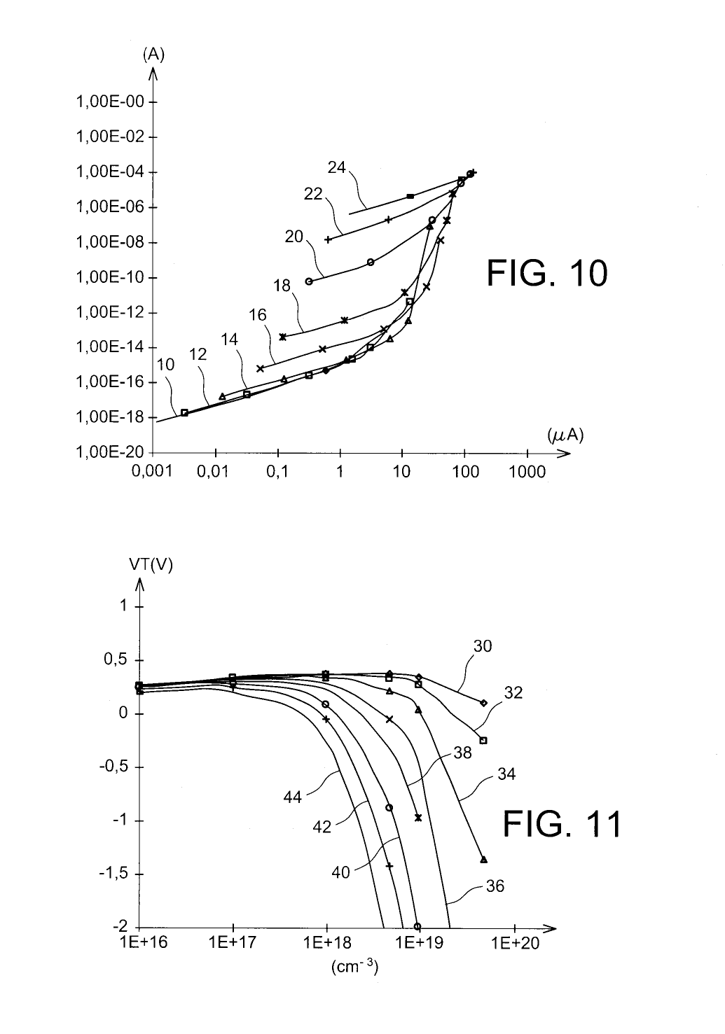

FIGS. 9A to 9E represent the steps of a method to produce an integrated circuit with junctionless depletion-mode FET devices, forming the subject of the present invention, according to a particular embodiment,

FIGS. 10 and 11 represent measurement curves used to optimise a junctionless depletion-mode FET device of an integrated circuit produced according to a method forming an object of the present invention,

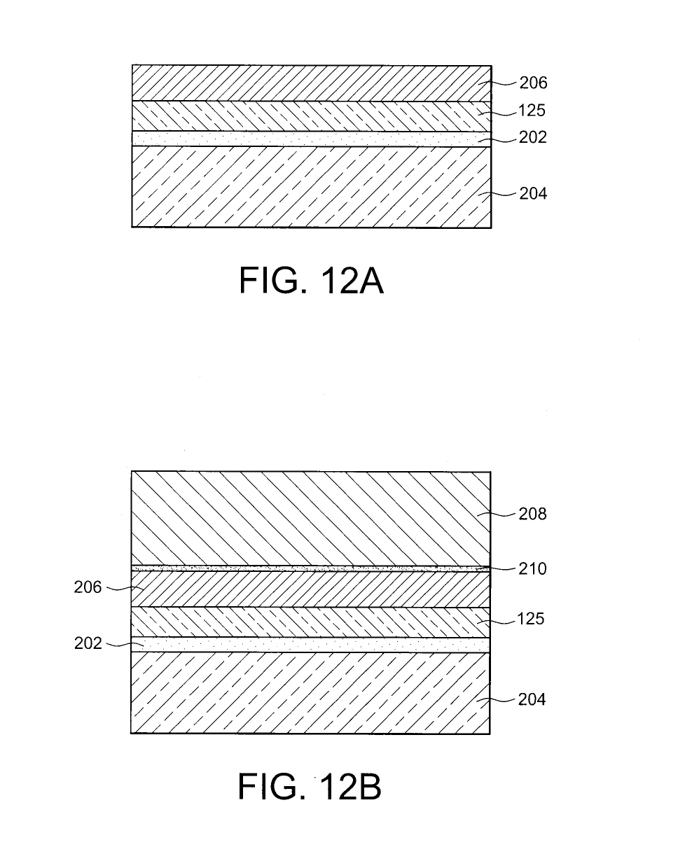

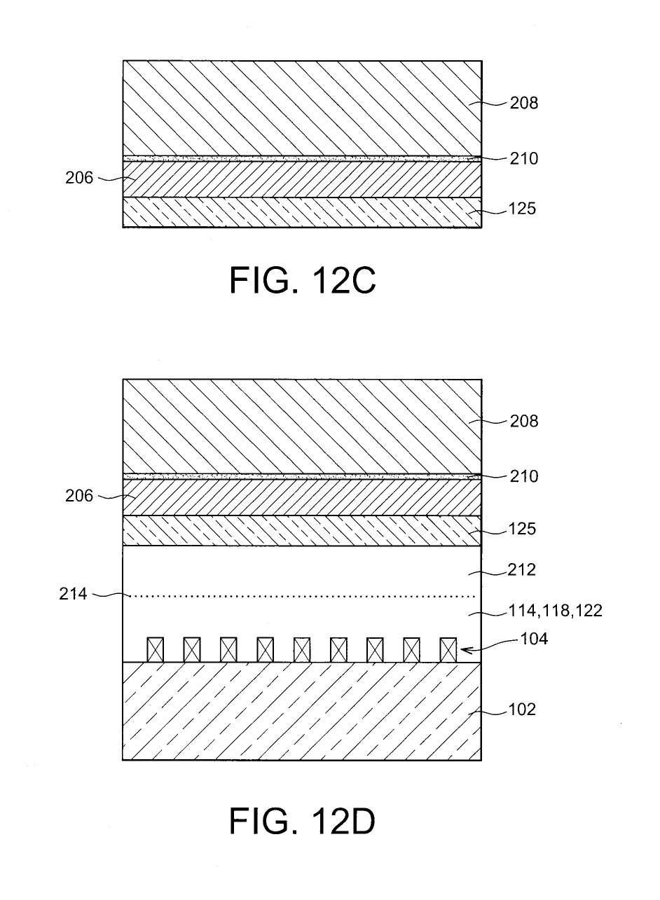

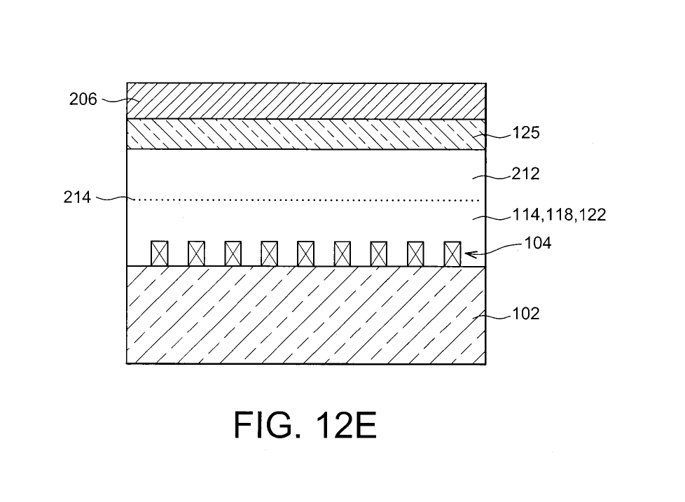

FIGS. 12A to 12E represent the steps of a method to produce an integrated circuit with junctionless depletion-mode FET devices, forming the subject of the present invention, according to a particular embodiment.

Identical, similar or equivalent portions of the various figures described below have the same numerical references, to make it easier to move from one figure to another.

The various portions represented in the figures are not necessarily represented at a uniform scale, in order to make the figures more readable.

The various possibilities (variants and embodiments) must be understood as not being mutually exclusive, and being able to be combined with one another.

### DETAILED ACCOUNT OF PARTICULAR EMBODIMENTS

Reference is first made to FIG. 1, which represents an integrated circuit 100 with junctionless depletion-mode FET devices 126 according to a first embodiment.

Integrated circuit 100 includes a substrate 102, for example comprising a semiconductor such as silicon, and of the bulk type or SOI (silicon on insulator) type or FD-SOI (fully depleted silicon on insulator) type, or again of the PD-SOI (partially depleted silicon on insulator) type, in which MOSFET transistors 104 are produced. Each of these MOSFET transistors 104, for example of the nMOS type, has a P type channel area 106 and N+ type source and drain areas 108 formed in substrate 102. Channel 106 is topped by a gate dielectric 110 and a gate 112.

Substrate 102 and transistors 104 are covered by a first dielectric layer 114, for example made of SiO₂, on which a first level of electrical interconnections 116 is formed. A second dielectric layer 118 covers first dielectric layer 114 and first level of electrical interconnections 116. A second level of electrical interconnections 120 is formed on second dielectric layer 118. Finally, a third dielectric layer 122 covers second dielectric layer 118 and second level of electrical interconnections 120.

Levels of electrical interconnections 116, 120 are formed, for example, by parts of electrically conductive material, for example metal. Vias 124, also made of an electrically conductive material such as metal, are produced through dielectric layers 114 and 118 in order to electrically connect electrical interconnection levels 116, 120 to one another and/or to transistors 104, in order to contact source and drain areas 108 and gates 112 of these transistors 104.

Integrated circuit 100 may, generally, include a greater or lesser number of levels of electrical interconnections positioned between dielectric layers 114, 118, 122. In addition, dielectric layers 114, 118 and 122, when they all are made from the same material, can be considered as a single dielectric layer in which levels of electrical interconnections 116 and 120 are positioned. However, dielectric layers 114, 118 and 122 may also be made of different dielectric materials.

Third dielectric layer 122 is covered with a thin crystalline semiconductor layer 125, for example made of silicon, which is less than approximately 100 nm thick, for example doped uniformly (same concentration of dopants along layer 125) and with the same type of doping (N or P). Junctionless depletion-mode FET transistors 126 are produced in thin crystalline semiconductor layer 125. These transistors 126 are electrically insulated from one another by dielectric parts 128, for example made of SiO₂, formed all the way through crystalline thin layer 125, around transistors 126. It is also possible that transistors 126 are insulated from one another by mesa-type insulation, where dielectric parts 128 are replaced in this case by empty areas. In another variant, it is also possible for dielectric parts 128 to form part of a layer of dielectric material covering transistors 126.

An example of such a junctionless depletion-mode FET transistor 126 is represented seen from above in FIG. 2. This transistor 126 includes a part of the thin layer of semiconductor 125, for example doped uniformly with the same type of doping, for example N-doped. This doped silicon part forms a source 130, a drain 132 and a channel 134 (the reference can be seen in FIG. 1) of junctionless depletion-mode FET transistor 126. Channel 134 is positioned under a gate 136 which is doped with a second type of doping, advantageously opposite the doping of the part of thin layer 125, for example of the P type, and a gate dielectric 138. Gate 136 may be made from a metal material.

In a variant embodiment transistor 126 may include a floating gate. In this case, gate dielectric 138 is replaced by a stack of parts of materials enabling a store of electrical charges to be produced, i.e. a store of data, in a storage part of this stack.

For example, when integrated circuit 100 is a flash memory, each of transistors 126 may include, between the active area forming the channel of the transistor and the gate of the transistor, a stack formed of a storage part, for example made of Si or SiN, positioned between two parts of dielectric material, for example made of SiO₂.

Compared to a conventional MOSFET transistor, junctionless depletion-mode FET transistor 126 has no p-n junction between source 130 and channel 134, or between drain 132 and channel 134. In such a transistor, source 130, drain 132 and channel 134 are formed by a semiconductor part doped uniformly with the same type of conductivity. When a zero voltage is applied to gate 136, the part of semiconductor layer 125 forming source 130, drain 132 and channel 134 is fully depleted, preventing conduction of the current between source 130 and drain 132. By applying an appropriate voltage to the gate, for example a positive voltage when channel 134 is of the N type, a non-depleted area is created which has the properties of a resistor, and which is able to conduct a current between source 130 and drain 132.

It should be noted that the thinner layer of silicon 125, the more easily total depletion is obtained in channel 134. Thus, a thin layer 125 of thickness of between approximately 3 nm and 100 nm will preferably be chosen, depending on the level of doping of layer 125. The lower the doping level the more easily total depletion of the channel is obtained.

However, the lower this level of doping, the higher the resistances of the source and drain.

Optimisation of the doping and thickness of the channel may thus be accomplished experimentally: for a given gate length, a channel thickness is chosen which enables all the technological steps to be implemented easily, enabling integrated circuit 100 to be produced, including the electrical contacts of the source and drain. This thickness may for example be between approximately 3 nm and 100 nm, and may for example be equal to approximately 10 nm. The doping produced in layer 125 may then be the maximum achievable doping which does not cause complete amorphisation of layer 125 before recrystallisation following a subsequent thermal activation. Complete amorphisation of layer 125 would indeed eliminate the monocrystalline property of this layer 125.

Optimisation is thus successful if the current can be blocked satisfactorily, and if the value of the current in the on state is sufficient for the implemented application. If it is desired to increase the ON current level of the device, the doping of layer 125 may be increased until the leakage level becomes intolerable. In addition, if it is desired to reduce the leakage level of the device, its doping and/or the thickness of layer 125 may then be reduced until the ON current level is too low for the sought application.

Bearing in mind that FET transistors 126 are junctionless transistors, it is therefore possible to produce them after having secured thin layer 125 to third dielectric layer 122, having taken care to implant the dopants in thin silicon layer 125 and to activate these dopants thermally before rigidly connecting thin silicon layer 125 with third dielectric layer 122, by this means preventing the lower levels of electrical interconnections 116 and 120 and MOS transistors 104 from being subjected to the thermal budgets attained on thermal activation of the dopants implanted in thin silicon layer 125.

Integrated circuit 100 as represented in FIG. 1 can be produced. However, it is also possible to produce above junctionless depletion-mode FET transistors 126 other levels of electrical interconnections and/or other levels of junctionless depletion-mode FET devices. It is also possible to cover the junctionless depletion-mode FET transistors by a dielectric layer in order to secure integrated circuit 100 to another integrated circuit.

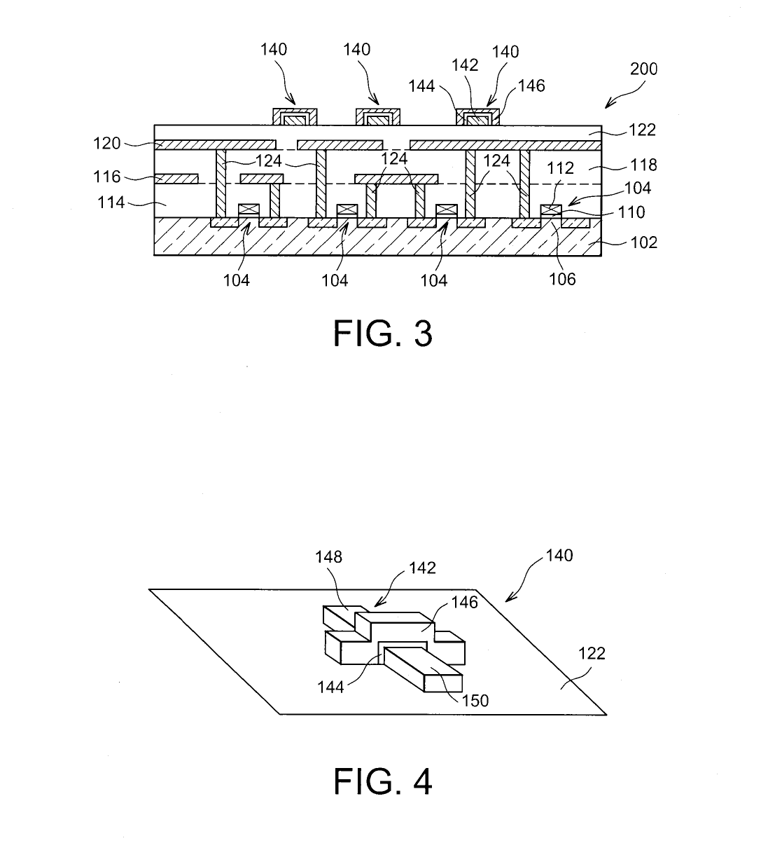

Reference is made to FIG. 3, which represents an integrated circuit 200 with junctionless depletion-mode FET devices 140 according to a second embodiment. Compared to integrated circuit 100, integrated circuit 200 includes junctionless depletion-mode FET transistors 140 which do not include parts of thin silicon layer 125 which are electrically insulated from the remainder of layer 125 by parts of dielectric material, but include uniformly doped silicon nanowires 142 obtained by etching in thin silicon layer 125. An example of such a junctionless depletion-mode FET transistor 140 is represented in FIG. 4. In this FIG. 4 a single nanowire 142 is represented. However, junctionless depletion-mode FET transistor 140 may include one or more nanowires 142. Nanowire 142 is partially covered by a gate dielectric 144 and by a gate 146, where the part of nanowire 142 located under gate dielectric 144 forms the channel of FET transistor 140. Nanowire 142 also forms a source 148 and a drain 150 of junctionless depletion-mode FET transistor 140. The thickness of nanowire 142 is for example equal to approximately 10 nm and may have a level of doping equal to approximately 10¹⁹ cm⁻³.

In a similar manner to FET transistor 126 which was previously described in connection with FIGS. 1 and 2, junctionless depletion-mode FET transistor 140 has no p-n junction between the channel and the source and between the channel and the drain. The operation of junctionless depletion-mode FET transistor 140 is similar to that of FET transistor 126.

In a variant embodiment, each of junctionless depletion-mode FET transistors 140 may include several semiconductor nanowires, where each nanowire forms a channel, a source and a drain, and is covered in the area of the channel by a gate which is common to all the nanowires of junctionless depletion-mode FET transistor 140. The drains of the nanowires are electrically connected to one another, as are the sources of the nanowires, which sources are electrically connected to one another.

In addition, as with integrated circuit 100, it is also possible to produce above junctionless depletion-mode FET transistors 140 other levels of electrical interconnections and/or other electronic levels including junctionless depletion-mode FET devices.

Optimisation of the doping and of the thickness of the channel can, here again, be accomplished experimentally, in a manner comparable to integrated circuit 100.

The curves represented in FIG. 10 show the current (in A) in the OFF state normalised at Vg=Vt−(⅓)*V_{DD} as a function of the current (in μA) in the ON state normalised at Vg=Vt+⅔*V_{DD}, where Vg is a voltage applied to the gate of FET transistor 140, Vt is the threshold voltage of FET transistor 140 and V_{DD} is the supply voltage of FET transistor 140, for different diameters of semiconductor nanowire 142. The values of the current in the ON state increase as doping increases, in this case between approximately 10¹⁶ cm⁻³ and 5·10¹⁹ cm⁻³. Graphs 10, 12, 14, 16, 18, 20, and 24 correspond respectively to a nanowire diameter equal to 3 nm, 5 nm, 10 nm, 20 nm, 30 nm, 50 nm, 70 nm and 100 nm. These graphs illustrate the compromise made between doping and thickness of the thin layer from which nanowire(s) 142 is/are produced, and the values of the currents obtained in the ON and OFF states. This diagram represents qualitative trends for a given gate length value, equal to approximately nm. The graphs are obtained in this case for a structure including nanowires with a fully coating gate, which constitutes an ideal case for electrostatic control. In the case of a partially coating gate or planar gate the qualitative trends would be roughly similar, but for smaller thicknesses or diameters.

From the curves represented in FIG. 10 it can therefore be seen that the smaller the diameter the lower the level of leakage, due to an improved electrostatic control being obtained, but the lower the current level in the ON state of the transistor.

In addition, the higher the doping the lower the resistivity of the channel and the series resistances, and the higher the current. Above a certain level of doping the leakage level can thus suddenly increase since the transistor is not fully depleted. The corresponding doping/thickness pair must therefore be avoided.

The graphs represented in FIG. 11 represent the threshold voltage of a functionless depletion-mode NMOS transistor including a gate material of the “mid-gap” type, for example made of TiN, as a function of the doping level implemented in the active layer of the transistor. Graphs 30, 32, 34, 36, 38, 40, 42 and 44 correspond respectively to an active layer of thickness equal to approximately 3 nm, 5 nm, 10 nm, 20 nm, 30 nm, 50 nm, 70 nm and 100 nm.

This threshold voltage is preferably between one quarter and half the supply voltage, for example equal to approximately 0.4 V for a supply at 1 volt in the case of a logic application.

From the graphs of FIG. 11 it can be seen that with excessively high dopings the threshold voltage drops suddenly. This is explained by the difficulty in blocking the highly doped transistor, since not all the active layer can be depleted. In the case of a flash memory application, its range of variation may be much broader, and can be of several volts, and also depends on the charges stored in the storage layer.

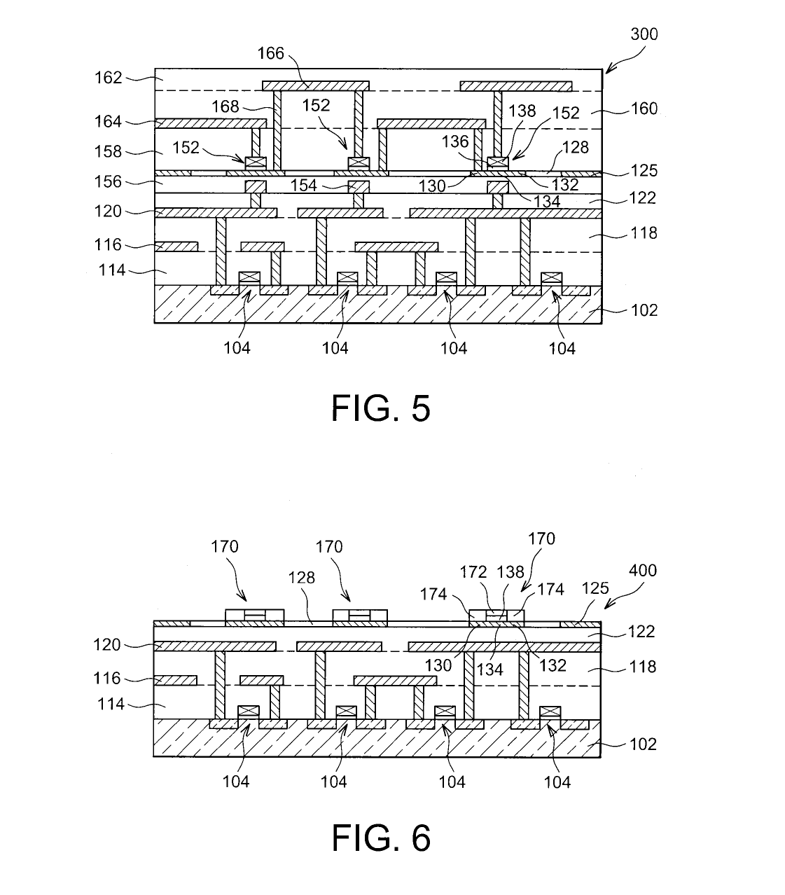

Reference is now made to FIG. 5, which represents an integrated circuit 300 with junctionless depletion-mode FET devices 152 according to a third embodiment.

Compared to integrated circuit 100 which was previously described in relation to FIG. 1, integrated circuit 300 includes junctionless depletion-mode FET transistors 152 which are different to previously described transistors 126. Indeed, compared to FET transistors 126, each of FET transistors 152 also includes a back gate positioned opposite channel 134 of transistor 152. These back gates 154 are produced using parts of electrically conductive material, for example metal, positioned on third dielectric layer 122 and covered by another dielectric layer 156 positioned between third dielectric layer 122 and thin silicon layer 125. Thin parts of dielectric layer 156 are sandwiched between back gates 154 and channel areas 134, forming back gate dielectrics. The operation of junctionless depletion-mode FET transistors 152 is comparable to that of FET transistors 126, except that the depletion area may be formed, in the channel, by an appropriate voltage applied to front gate 136 of FET transistor 152 and/or to back gate 154 of FET transistor 152.

In addition, in the example of FIG. 5, junctionless depletion-mode FET transistors 152 are covered by several dielectric layers 158, 160 and 162 in which levels of electrical interconnections 164, 166 and conductive vias 168 are produced which connect, for example, these levels of electrical interconnections 164, 166 to contact areas (gate, source or drain) of FET transistors 152.

An integrated circuit 400 with junctionless depletion-mode FET devices 170 according to a fourth embodiment is represented in FIG. 6.

In this fourth embodiment, junctionless depletion-mode FET devices 170 are chemical sensors of the ChemFET type. Compared to a junctionless depletion-mode FET transistor, such a ChemFET 170 sensor includes, in the place of the electrically conductive material part forming the gate of the FET transistor, a part 172 of material which is chemically sensitive to certain charges intended to be detected by ChemFET sensor 170 and positioned between dielectric parts 174 covering the source and drain 132 of ChemFET sensor 170. In such a sensor the trapping of ions or the appearance of charges in the area of gate dielectric 138 causes a modification of the threshold voltage of ChemFET sensor 170 and leads to a variation of the current intended to flow in channel 134 between drain 132 and source 130 of sensor 170.

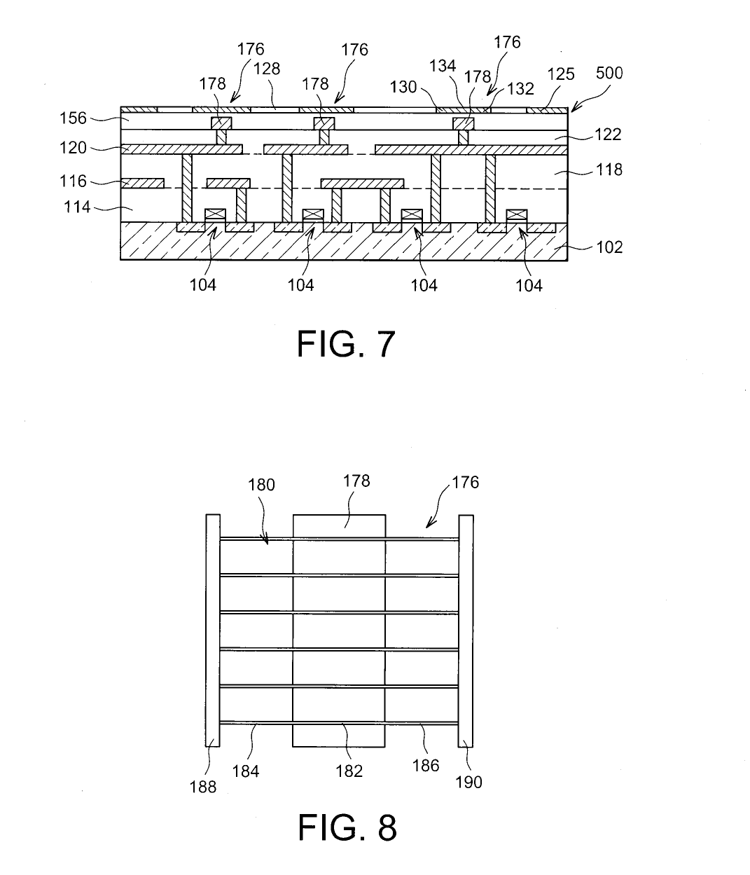

Reference is made to FIG. 7, which represents an integrated circuit 500 with junctionless depletion-mode FET devices 176 according to a fifth embodiment.

Compared to integrated circuit 100 which was described above in relation to FIG. 1, integrated circuit 500 includes junctionless depletion-mode FET transistors 176 including sources 130, drains 132 and channels 134 formed in thin crystalline semiconductor layer 125, but not including front gates. Whether or not depletion areas are formed in channels 134 of these transistors 176 is controlled by back gates 178, for example comparable to back gates 154 described above for FET transistors 152 of integrated circuit 300. The operation of junctionless depletion-mode FET transistors 176 is comparable to the operation of FET transistors 126 described above, except that the creation of depletion areas in the channels is controlled by applying voltages to back gates 154.

In integrated circuits 100, 300, 400 and 500 described above, each of the junctionless depletion-mode FET devices includes a part of thin crystalline semiconductor layer 125 forming a channel 134, a source 130 and a drain 132, where this part is insulated from the remainder of thin layer 125 by dielectric parts 128. In a variant embodiment, these semiconductor parts may be replaced by multiple nanowires formed by etching in thin crystalline semiconductor layer 125. For example, FET transistor 176, described above in connection with integrated circuit 500, according to this variant embodiment, is represented in FIG. 8. In this FIG. 8, transistor 176 includes a back gate 178 and several nanowires of crystalline semiconductor 180. The parts of these nanowires 180 located above back gate 178 form channels 182, whereas the parts of nanowires 180 located either side of channels 182 respectively form sources 184 and drains 186. Sources 184 of nanowires 180 are connected electrically to an electrical source contact 188 common to all sources 184, and drains 186 of nanowires 180 are connected electrically to an electrical drain contact 190 common to all drains 186.

A description is now given, in connection with FIGS. 9A to 9E, of the steps of a method to produce integrated circuit 100 according to a particular embodiment.

As represented in FIG. 9A, the CMOS circuit including different MOS transistors 104 is first produced in substrate 102. The steps for production of such a CMOS circuit are known and are not described in detail here.

Levels of electrical interconnections 116, 120 are then produced in dielectric layers 114, 118 and 122 which cover the CMOS circuit previously produced in substrate 102. The steps implemented to produce these levels of electrical interconnections and these dielectric layers 114, 118, 122 are also known and not described in detail here.

From another substrate, for example of the SOI type, including a dielectric layer 202, for example made of SiO₂, positioned between thin crystalline silicon layer 125 and a massive silicon layer 204, thin layer 125 is doped. The type and level of doping accomplished is that which it is desired to obtain in the semiconductor parts intended to form the sources, drains and channels of the junctionless depletion-mode FET transistors 126, and is for example between approximately 10¹⁸ cm⁻³ and 10²⁰ cm⁻³. This doping may be accomplished all the way through thin layer 125, or alternatively only in a portion of thin layer 125. For example, if it is desired to produce several types of junctionless depletion-mode FET transistors in integrated circuit 100 (different levels of doping and/or types of doping), several separate parts of thin crystalline semiconductor layer 125 may be doped differently. As a variant of the SOI substrate, a pseudo-substrate of SiGe may be used in which layer 202 of the SOI substrate is replaced by a gradual buffer made of SiGe.

The dopants implanted in thin crystalline semiconductor layer 125 are then thermally activated. Given that this thermal activation is accomplished when thin layer 125 is not yet secured to the structure including the CMOS circuit produced in substrate 102, and levels of interconnection 116, 120, the temperatures reached during this thermal activation have no impact on these elements.

As represented in FIG. 9C, a rigid connection is then made, for example by bonding, of thin crystalline semiconductor layer 125 with dielectric layer 122 covering electrical interconnections 116 and 120. This transfer by bonding is implemented at low temperatures, for example of between approximately 100° C. and 650° C., and preferably of less than approximately 450° C., in order not to damage the CMOS circuit and levels of electrical interconnections 116, 120.

In a variant, before rigidly attaching thin layer 125 with dielectric layer 122, other intermediate layers may be formed on thin layer 125, or on dielectric layer 122, such as a bonding layer, for example a thermal oxide layer, and/or a dielectric layer intended to form back gate dielectrics. Other types of layers, for example a barrier layer and/or a stop layer, may also be deposited on layer 125.

Massive silicon layer 204 and dielectric layer 202 are then removed, for example by etching dielectric layer 202 (FIG. 9D).

In thin layer 125 the active areas of junctionless depletion-mode FET transistors 126 intended to be produced are then insulated. To do so, thin layer 125 is then for example etched in localised fashion around these active areas. It is also possible, as represented in FIG. 9E, to produce parts of dielectric material 128 around these active areas, obtained for example by oxidation of the silicon of thin layer 125.

Integrated circuit 100 is then completed by producing gate dielectrics 138 and gates 136 above the previously insulated active areas in thin layer 125, forming integrated circuit 100 represented in FIG. 1.

The different steps implemented after the rigid connection of thin crystalline semiconductor layer 125 with the CMOS circuit and lower levels of interconnections 116, 120 are so implemented at temperatures called “cold” temperatures, i.e. below approximately 450° C., in order not to damage the CMOS circuit comprising transistors 104 and levels of interconnections 116 and 120.

This method may be continued by producing other levels of electrical interconnections and/or other electronic levels including junctionless depletion-mode FET devices by repeating the steps described in connection with FIGS. 9B to 9D, by stacking these additional layers above FET transistors 126, without damaging these FET transistors 126 or the lower electrical interconnections and CMOS circuits.

In a variant embodiment, crystalline semiconductor layer 125 may be rigidly connected to substrate 102 (in particular with dielectric layer 122 in between) not directly from an SOI substrate, but by means of a temporary handle. Thus, from the stack represented in FIG. 12A including massive semiconductor layer 204, dielectric layer 202, crystalline semiconductor layer 125 and a stack of gate materials 206 intended to form, for example, gates 136 and gate dielectrics 138 of the FET devices intended to be produced from crystalline semiconductor layer 125, temporary handle 208 is rigidly connected to stack of gate materials 206 with a bonding layer 210 in between (FIG. 12B).

The materials attached to the back face of crystalline semiconductor layer 125 are then removed, i.e. massive layer 204 and dielectric layer 202 are then removed, for example by etching dielectric layer 202 (FIG. 12C).

The assembly obtained is then rigidly connected to substrate 102, on which are produced one or more MOS electronic circuits 104 and/or one or more levels of electrical interconnections (FIG. 12D). This rigid connection is accomplished, for example, by means of bonding oxides 212 and 122 formed on the two structures intended to be assembled, rigidly connected to one another in a bonding interface 214.

Finally, temporary handle 208 is detached from the assembly, and bonding layer 210 is also eliminated (FIG. 12E).

This variant described in connection with FIGS. 12A to 12E enables the back face of crystalline semiconductor layer 125 to be rigidly attached to substrate 102, not its front face, as in the example previously described in connection with FIGS. 9A to 9E.

The junctionless depletion-mode FET device or devices are then produced from layer 125 and from stack 206, starting either by a lithography in layer 125 in order to define the semiconductor areas of the FET devices (by then etching layer 125 and stack 206), or by a lithography of the gate stacks in the materials of stack 206.

1-12. (canceled)

13. A method for producing an integrated circuit, comprising, in this order:
a) producing at least one MOS electronic circuit and/or at least one level of electrical interconnections on a substrate;
b) uniformly implanting dopants in at least a portion of a layer of crystalline semiconductor;
c) thermally activating the dopants implanted in the portion of the layer of crystalline semiconductor;
d) rigidly connecting the layer of crystalline semiconductor to the substrate;
e) producing at least one junctionless depletion-mode FET device including a part of the portion of the layer of crystalline semiconductor.

14. The method according to claim 13, further comprising, between a) and d), producing at least one layer comprising a dielectric material, covering the substrate and the MOS electronic circuit and/or the level of electrical interconnections, wherein the layer of crystalline semiconductor is rigidly connected to the substrate, in d), with the layer comprising the dielectric material in between.

15. The method according to claim 14, further comprising, during producing the layer comprising the dielectric material, producing multiple levels of electrical interconnections positioned in the layer comprising the dielectric material, wherein the MOS electronic circuit includes plural MOS transistors electrically connected to the levels of electrical interconnections by vias formed in the layer comprising the dielectric material.

16. The method according to claim 13, in which the layer of crystalline semiconductor is a surface layer of an SOI substrate, and further comprising, between d) and e), separating the layer of semiconductor and other elements of the SOI substrate.

17. The method according to claim 13, in which the e) producing the junctionless and depletion-mode FET device is implemented at a temperature of less than approximately 450° C.

18. The method according to claim 13, in which the e) producing the junctionless depletion-mode FET device includes the production of an area of electrical insulation in the layer of crystalline semiconductor, around the part of the portion of the layer of crystalline semiconductor.

19. The method according to claim 13, in which the e) producing the junctionless depletion-mode FET device includes etching of the layer of crystalline semiconductor around the part of the portion of the layer of crystalline semiconductor, wherein the part forms one or more nanowires of uniformly doped crystalline semiconductor.

20. The method according to claim 13, further comprising, after the e) producing the junctionless depletion-mode FET device, producing at least one second layer comprising a dielectric material covering at least the junctionless depletion-mode FET device, and at least one level of electrical interconnections positioned in the second layer comprising the dielectric material connected electrically to the junctionless depletion-mode FET device by vias formed in the second layer comprising the dielectric material.

21. The method according to claim 13, further comprising, after the c), depositing at least one gate dielectric or the production of a stack including at least one part of material configured to store electrical charges positioned between at least two parts of dielectric material, on the layer of crystalline semiconductor, and producing at least one front gate and/or one back gate opposite the channel of the junctionless depletion-mode FET device, wherein the gate dielectric or the stack is positioned between the front gate and the channel and/or between the back gate and the channel.

22. The method according to claim 13, further comprising, between b) and c) or between c) and d), depositing, on the layer of crystalline semiconductor, at least one bonding layer and/or one barrier layer and/or one stop layer.

23. The method according to claim 13, further comprising, before d), rigidly connecting the layer of crystalline semiconductor to a temporary handle, and further comprising, between d) and e), eliminating the temporary handle.

24. The method according to claim 13, in which the junctionless depletion-mode FET device is a transistor including a channel, a source, and a drain formed by the uniformly doped part of crystalline semiconductor, or a flash memory transistor, or a chemical sensor of junctionless depletion-mode ChemFET type.
